(19) United States
(12) Patent Application Publication
(10) Pub. No.: US 2021/0088293 A1
(43) Pub. Date: Mar. 25, 2021

(54) HEAT TRANSFER ASSEMBLY

(71) Applicant: ASIA VITAL COMPONENTS CO., LTD., New Taipei City (TW)

(72) Inventor: Ching-Hang Shen, New Taipei City (TW)

(21) Appl. No.: 16/576,787

(22) Filed: Sep. 20, 2019

(51) Int. Cl. F28F 3/12; F28D 15/04; F28F 21/08

(52) U.S. Cl. CPC F28F 3/12; F28D 15/046; F28F 21/084; F28F 21/085; F28F 2275/14; F28F 2245/02; F28F 2275/025; F28F 2275/06; F28F 21/086

(57) ABSTRACT

A heat transfer assembly includes a first plate, a second plate, and an engaging unit. The first plate has a first side and a second side, and the second plate has a third side and a fourth side. The third side is attached to the first side, which defines a sealed chamber between the first and second plates. The fourth side has an accommodating portion that is in thermal contact with at least a heat source. The engaging unit is disposed adjacent to the accommodating portion, and engaged with the heat source, thereby allowing the heat transfer assembly to be in direct contact with the heat source. Therefore, a lower thermal resistance can be achieved by the direct contact, and no penetration to the heat transfer assembly prevents the assembly from vacuum leaks.

### BACKGROUND OF THE INVENTION

### 1. Field of the Invention

The present invention relates to a heat transfer assembly, in particular to, a heat transfer assembly that provides a tight connection between the heat transfer assembly and a heat source without penetrating an airtight chamber of the heat transfer assembly.

### 2. Description of the Related Art

As the performance of existing electronic apparatus is getting higher, the electronic components thereof for signal processing and computing produce a more significant amount of heat than ever. In general, a heat transfer component such as a heat pipe, heat sink, or vapor chamber, etc, which is in direct contact with an electronic component producing heat for increasing heat transfer efficiency, is used to prevent the electronic component from a failure scenario due to a high temperature.

A vapor chamber is a two-dimensional heat transfer application for wider heat dissipation, which is different from a one-dimensional heat transfer of a heat pipe and is suitable for a relatively small space.

A conventional vapor chamber is mounted on a base plate when being used, and transfers heat produced by the components on the base plate. In general, the method of mounting the conventional vapor chamber onto the plate is as follow: each of the four corners of the vapor chamber is formed with a hole through which a copper column having an internal thread is disposed; the four spots of the plate relative to the four corners of the vapor chamber are formed with an opposing hole, respectively; and a threaded element is threadedly engaged with the internal thread of the copper column and the opposing hole of the plate at the four corners. So, the vapor chamber can be fixedly mounted onto the base plate without damaging an inner chamber of the vapor chamber. However, this mounting method results in a higher thermal resistance, because the four copper columns are disposed within the four corners of the vapor chamber, which are away from the components on the plate that produce heat and thus no direct contact is between the vapor chamber and the heat-producing components. For addressing the issue of no direct contact, a person in the conventional art disposes the copper column within the vapor chamber in a spot adjacent to the heat-producing components on the opposing plate, with the copper column penetrating the inner chamber of the vapor chamber. Although thermal resistance is improved by the closer connection, the inner chamber of the vapor chamber is no longer in a vacuum due to air leakage caused by the copper column penetrating the inner chamber. Furthermore, the path of working fluids inside the inner chamber may be blocked due to the damage resulted from the penetrating copper column, which decreases heat transfer efficiency, and in the worst scenario, causes the leakage of the fluids that leads to complete failure of the heat transfer of the vapor chamber.

In addition, referring to FIGS. 9 and 10, a vapor chamber structure is shown. A body 51 has separate first and second plates 511 and 512, with an extending portion 513 disposed on the perimeter of the body that is in contact with the second plate, defining a closed chamber 514. A groove 5111 is disposed on the first plate 511 away from the extending portion 513, and is in contact with the second plate 512. An opening 52 penetrates the groove 5111 of the first plate 511 and the second plate 512, wherein the groove 5111 includes a circular outer surface 5112 in contact with an opposing circular edge surface 5121 on the second plate 512, the opening 52 is therefore isolated from the body 51. A spacer 53 extends between the first and second plates 511 and 512, and a capillary wick 54 is disposed with the closed chamber 514. However, although an airtight seal is achieved in this structure by the design of the groove 5111 that supports the body, other issues occur. The groove significantly reduces the room for the vapor-liquid flow inside the vapor chamber, and results in a reduced contact area between the vapor chamber and a heat source, thereby reducing heat transfer efficiency.

Therefore, the above-mentioned conventional vapor chambers have shortcomings as follow: 1. higher thermal resistance, 2. reduced contact area for heat transfer, and 3. reduced heat transfer efficiency.

### SUMMARY OF THE INVENTION

Accordingly, for addressing the shortcomings of the prior arts, the main purpose of the present invention is to provide a heat transfer assembly that provides a tight connection between the heat transfer assembly and a heat source without penetrating an airtight chamber of the heat transfer assembly.

To achieve the above-mentioned purpose, the present invention is provided with a heat transfer assembly comprising a first plate, a second plate, and an engaging unit; the first plate having a first side and a second side; the second plate having a third side and a fourth side, the third side attached to the first side which defines a sealed chamber between the first and second plates, the fourth side having an accommodating portion that is in thermal contact with at least a heat source; and the engaging unit disposed adjacent to the accommodating portion, and engaged with the heat source.

The heat transfer assembly of the present invention enables the assembly to be tightly connected with the heat source without penetrating a sealed chamber of the assembly, and ensures that the chamber inside the assembly is kept airtight.

### BRIEF DESCRIPTION OF THE DRAWINGS

FIG. 1 is an exploded perspective view of a first embodiment of a heat transfer assembly of the present invention;

FIG. 2 is a side cross-sectional view of the first embodiment of the heat transfer assembly of the present invention;

FIG. 3 is a side cross-sectional view of a second embodiment of the heat transfer assembly of the present invention;

FIG. 4 is a side cross-sectional view of a third embodiment of the heat transfer assembly of the present invention;

FIG. 5 is an exploded perspective view of a fourth embodiment of the heat transfer assembly of the present invention;

FIG. 6 is a side cross-sectional view of a fifth embodiment of the heat transfer assembly of the present invention;

FIG. 7 is an exploded perspective view of a sixth embodiment of the heat transfer assembly of the present invention;

FIG. 8 is an exploded perspective view of the sixth embodiment of the heat transfer assembly of the present invention;

FIG. 9 is a top view of a conventional heat transfer device; and

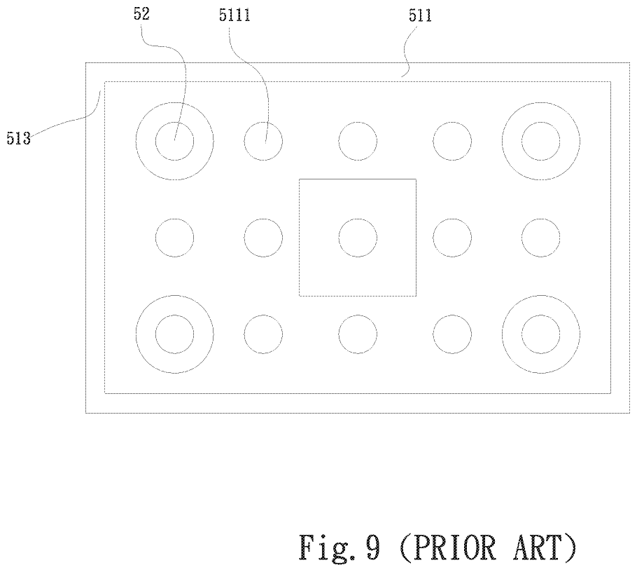

FIG. 10 is a side cross-sectional view of the conventional heat transfer device.

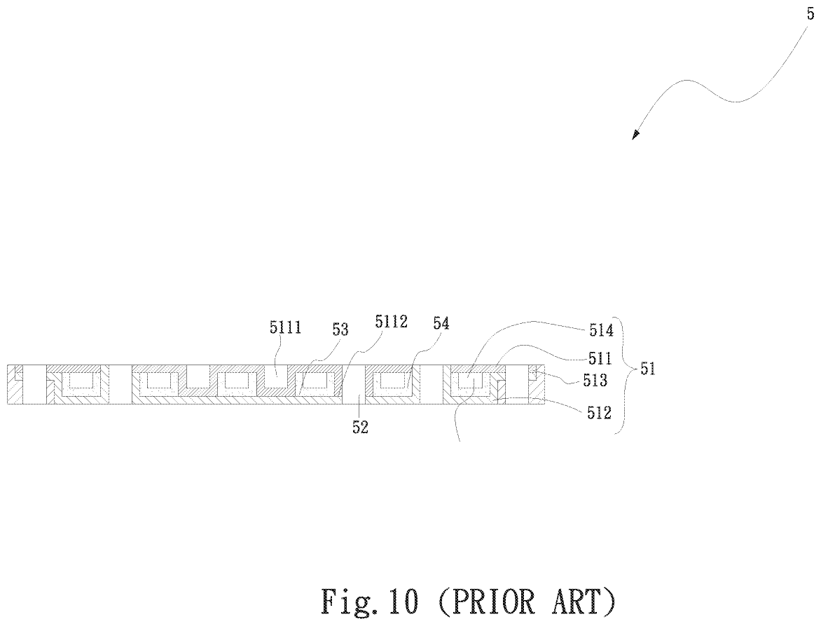

### DETAILED DESCRIPTION OF THE PREFERRED EMBODIMENTS

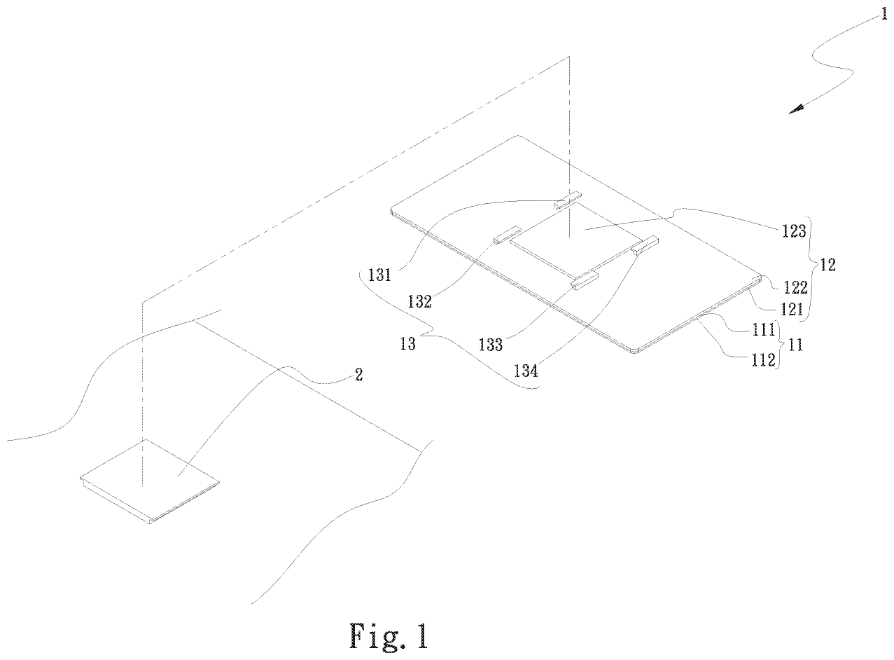

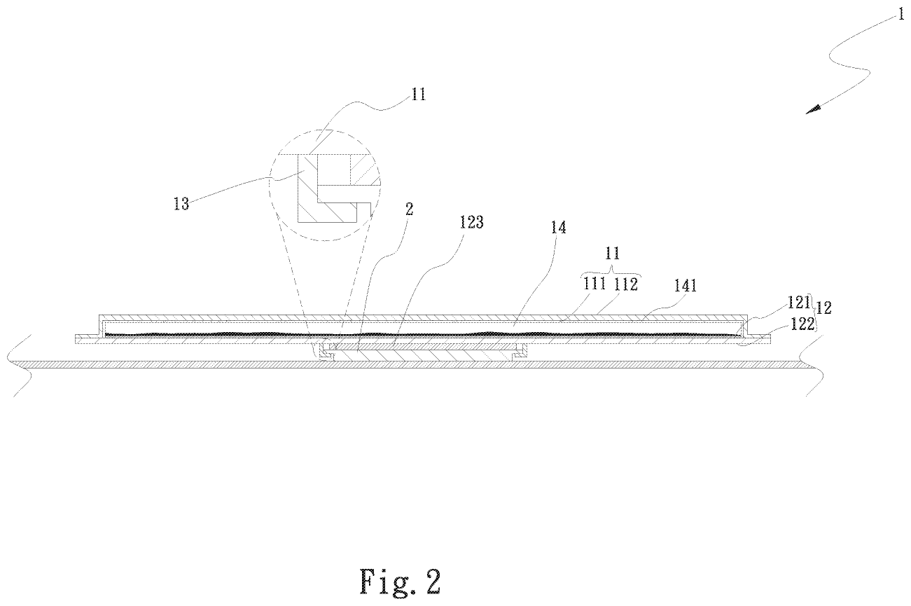

FIGS. 1 and 2 are exploded perspective view and side cross-sectional view of a first embodiment of a heat transfer assembly of the present invention, respectively. As shown in the FIGS., heat transfer assembly 1 includes a first plate 11, a second plate 12, and an engaging unit 13.

The first plate 11 has a first side 111 and second side 112, which are defined by the upper and lower sides of the first plate 11, respectively.

The second plate 12 has a third side 121 and fourth side 122. The third side 121 is attached to the first side 111, which defines a sealed chamber 14 between the first and second plates 11 and 12. The fourth side 122 has an accommodating portion 123 in thermal contact with at least a heat source 2.

The engaging unit 13 is disposed adjacent to the accommodating portion 123 to receive the heat source 2 therein. In this embodiment of the present invention, the engaging unit 13 is formed with a first engaging part 131, second engaging part 132, third engaging part 133, and fourth engaging part 134. The engaging unit 13 is integrally extended from the fourth side 122 of the second plate 12, or disposed on the fourth side by any of overmolding, welding, adhesively attaching, and hook-and-loop fastener.

The first, second, third, and fourth engaging parts 131, 132, 133, and 134 are disposed adjacent to the heat source 2, and enables the heat source 2 to be stuck therein.

The first and second plates 11 and 12 are formed from any of copper, aluminum, stainless steel, and titanium, and the first plate 11 can be formed from a material the same as or different from the second plate 12.

A hydrophilic coating 141 is coated on the first side 111 of the first plate 11 relative to the sealed chamber 14, thereby improving the efficiency of the vapor-liquid flow of working fluids inside the sealed chamber 14.

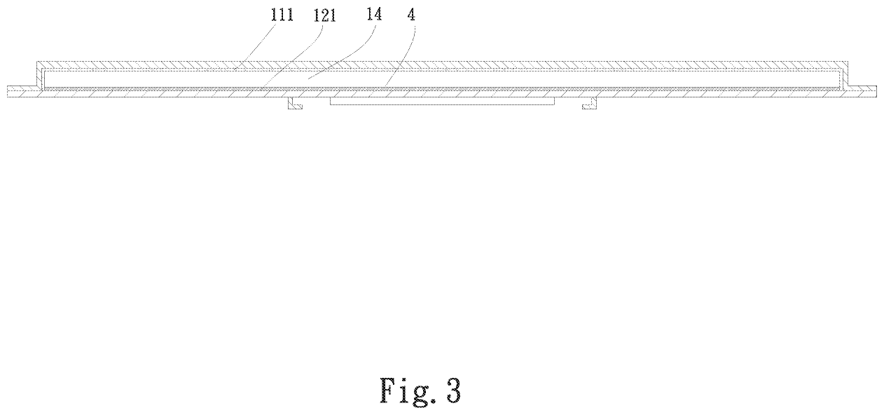

FIG. 3 is a side cross-sectional view of a second embodiment of the heat transfer assembly of the present invention. As shown in the FIG., some structures of this embodiment are the same as the above-mentioned first embodiment, and here are not described again. The difference between this embodiment and the first embodiment is that the third side 121 of the sealed chamber 14 has a capillary wick 4. The capillary wick 4 can be any of a mesh structure, fiber structure, and structure having a porous material. In an embodiment where the capillary wick 4 is the structure having a porous material, the wick can be formed locally or in a stacked way by electrochemical deposition, electroforming, 3D printing, or printing.

In an embodiment where the structure having a porous material is formed by the electrochemical deposition, the material thereof is any of copper, titanium, aluminum, and a metal with high thermal conductivity.

In an embodiment where the capillary wick is the mesh structure, the material of the wick is copper, aluminum, stainless steel or titanium, or combination thereof.

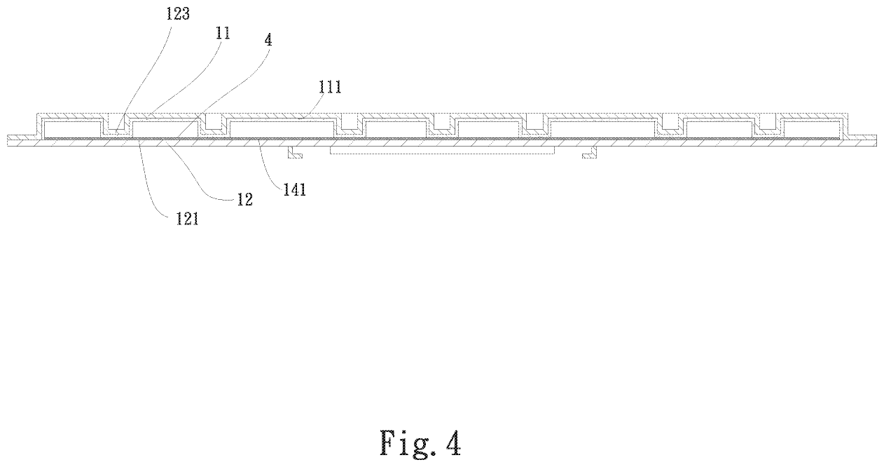

FIG. 4 is a side cross-sectional view of a third embodiment of the heat transfer assembly of the present invention. As shown in the FIG. 4, some structures of this embodiment are the same as the above-mentioned second embodiment, and here are not described again. The difference between this embodiment and the second embodiment is that a plurality of protrusions 123 extends from the first side 111 of the first plate 11 toward the third side 121 of the second plate 12 with their one side, and are in contact with the capillary wick 4 that is formed on the third side 121. Also, the other side of the plurality of protrusions 123 is recessed.

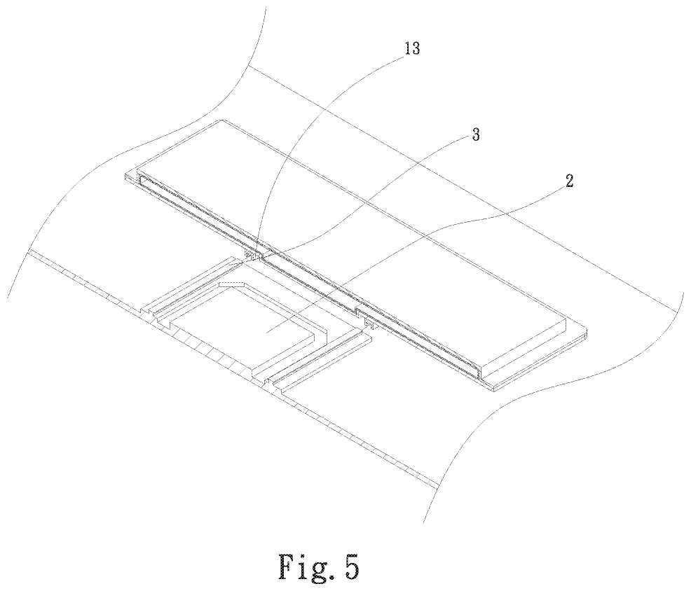

FIG. 5 is an exploded perspective view of a fourth embodiment of the heat transfer assembly of the present invention. As shown in the FIG. 5, some structures of this embodiment are the same as the above-mentioned first embodiment, and here are not described again. The difference between this embodiment and the first embodiment is that an engaging element 3 is disposed around the perimeter of the heat source. In this embodiment, the engaging element 3 is a pair of dovetail keys, and the engaging unit 13 is a pair of dovetail grooves, so that the pair of dovetail keys of the engaging element 3 can be engaged with the engaging unit 13.

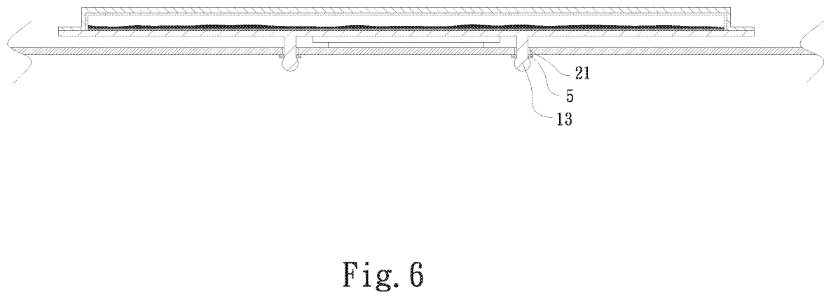

FIG. 6 is a side cross-sectional view of a fifth embodiment of the heat transfer assembly of the present invention. As shown in the FIG. 6, some structures of this embodiment are the same as the above-mentioned first embodiment, and here are not described again. The difference between this embodiment and the first embodiment is that the perimeter of the heat source 2 is formed with a plurality of holes 21 through which each open end of the engaging units 13 passes, and a c-type retaining rings 5 are used to prevent the engaging parts from moving.

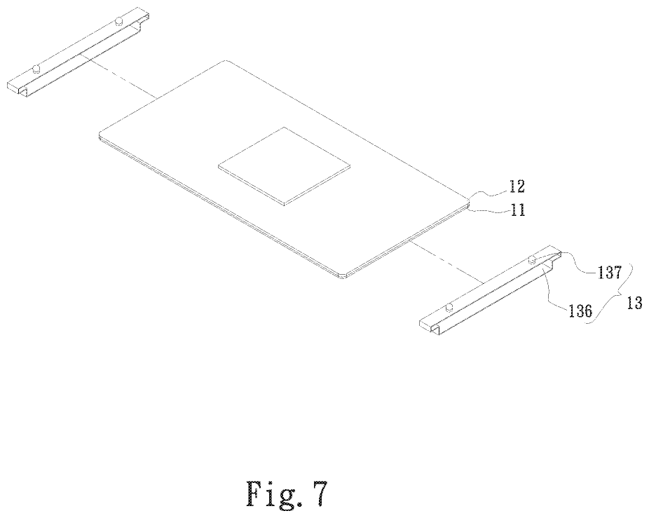

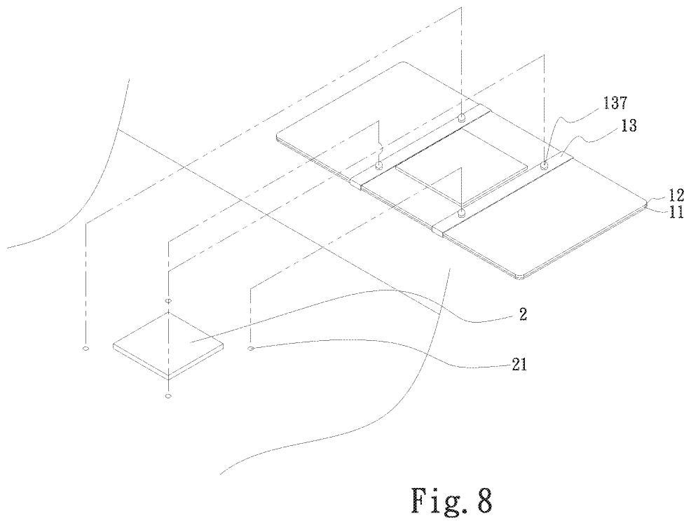

FIGS. 7 and 8 are exploded perspective views of a sixth embodiment of the heat transfer assembly of the present invention. As shown in the FIGS. 7 and 8, some structures of this embodiment are the same as the above-mentioned first embodiment, and here are not described again. The difference between this embodiment and the first embodiment is that the engaging unit 13 has a passing hole 136 through which the first and second plates 11 and 12 pass, and one side of the engaging unit 13 has at least a projection 137. Also, at least a hole 21 is disposed around the perimeter of the heat source 2 that allows the at least a projection 137 to pass through.

The main purpose of the present invention is to provide a heat transfer assembly having a vacuum chamber that can be engaged with a heat source by the engagement between engaging unit 13 and the engaging element 3 without penetrating the chamber. Accordingly, the vapor-liquid flow of working fluids inside the heat transfer assembly is not blocked and kept advantageous circulation. In addition, the efficiency of the vapor-liquid flow of working fluids inside the heat transfer assembly can be improved by the combination of the hydrophilic coating and capillary wick.

What is claimed is:

1. A heat transfer assembly, comprising:
a first plate having a first side and a second side;
a second plate having a third side and a fourth side, the third side attached to the first side which defines a sealed chamber between the first and second plates, the fourth side having an accommodating portion that is in thermal contact with at least a heat source; and
an engaging unit adjacent to the accommodating portion and receiving the heat source therein.

2. The heat transfer assembly according to claim 1, wherein the first side has a hydrophilic coating.

3. The heat transfer assembly according to claim 1, wherein a capillary wick is formed on the third side relative to the sealed chamber.

4. The heat transfer assembly according to claim 3, wherein the capillary wick is any of a mesh structure, fiber structure, and structure having a porous material.

5. The heat transfer assembly according to claim 3, wherein the capillary wick is formed by electrochemical deposition, electroforming, 3D printing, or printing.

6. The heat transfer assembly according to claim 5, wherein the material for the electrochemical deposition is any of copper, titanium, aluminum, and a metal with high thermal conductivity.

7. The heat transfer assembly according to claim 4, wherein the material of the mesh structure is any of copper, aluminum, stainless steel, and titanium.

8. The heat transfer assembly according to claim 1, wherein the material of the first and second plate are any of copper, aluminum, stainless steel, and titanium.

9. The heat transfer assembly according to claim 1, wherein the engaging unit is fixed together with the second plate by any of overmolding, welding, adhesively attaching, and hook-and-loop fastener.

10. The heat transfer assembly according to claim 3, wherein a plurality of protrusions extends from the first side toward the third side, and open ends of the plurality of protrusions is in contact with the capillary wick.

11. The heat transfer assembly according to claim 1, wherein the engaging unit has a first engaging part, a second engaging part, a third engaging part, and a fourth engaging part, and the heat source is stuck in the first, second, third, and forth engaging parts.

12. The heat transfer assembly according to claim 1, further comprising an engaging element, wherein the engaging element is a pair of dovetail keys and disposed around the perimeter of the heat source, the engaging unit is a pair of dovetail grooves, and the pair of dovetail keys of the engaging element is engaged with the engaging unit.

13. The heat transfer assembly according to claim 1, wherein the perimeter of the heat source is formed with a plurality of holes through which open ends of the engaging units pass, and c-type retaining rings secure the open ends in place.

14. The heat transfer assembly according to claim 1, wherein the engaging unit has a passing hole through which the first and second plates pass, one side of the engaging unit has at least a projection, and at least a hole is disposed around the perimeter of the heat source that allows the at least a projection to pass through.

15. The heat transfer assembly according to claim 1, wherein the engaging unit is integrally formed with the second plate.
